(19) United States
(12) Patent Application Publication
(10) Pub. No.: US 2014/0225099 A1
(43) Pub. Date: Aug. 14, 2014

(54) PLANAR LIGHT EMITTING DEVICE

(71) Applicant: PANASONIC CORPORATION, Osaka (JP)

(72) Inventors: Kazuyuki Yamae, Nara (JP); Shintaro Hayashi, Hyogo (JP)

(21) Appl. No.: 14/343,144

(22) PCT Filed: Dec. 28, 2012
(86) PCT No.: PCT/JP2012/082836

§ 371 Date: Mar. 6, 2014

(30) Foreign Application Priority Data
Dec. 19, 2011 (JP) 2011-276740

(51) Int. Cl. H01L 51/52

(52) U.S. Cl. CPC H01L 51/5259; H01L 51/5275
USPC 257/40

(57) ABSTRACT

The planar light emitting device according to the present invention includes: an organic electroluminescence element; a formation substrate of a light transmissive resin material being adjacent to a first surface of the organic electroluminescence element; a light outcoupling structure provided to the formation substrate and suppressing reflection of light emitted from the organic electroluminescence element at a surface of the formation substrate; a first moisture preventer with a moisture proof property being over a second surface of the organic electroluminescence element to cover the organic electroluminescence element; and a second moisture preventer with a moisture proof property covering the formation substrate to prevent moisture from passing through the formation substrate and reaching the first surface of the organic electroluminescence element. The second moisture preventer includes an overlap overlapping the first surface in the thickness direction of the organic electroluminescence element. The overlap is of a light transmissive material.

### TECHNICAL FIELD

The present invention relates to planar light emitting devices and particularly to a planar light emitting device with an organic electroluminescence element.

### BACKGROUND ART

In a known general structure of an organic electroluminescence element (hereinafter referred to as “organic EL element”), a transparent electrode used as an anode, a hole transport layer, a light emitting layer, an electron injection layer, and a cathode are stacked on a surface of a transparent substrate in this order. It is known that such an organic EL element is used to produce a planar light emitting device (lighting panel). In this organic EL element, light is produced in an organic light emitting layer in response to application of voltage between the anode and the cathode, and the produced light is emitted outside through the transparent electrode and the transparent substrate and goes outside.

The organic EL element gives a self-emission light in various wavelengths, with a relatively high yield. Such organic EL elements are expected to be applied for production of displaying apparatuses (e.g., light emitters used for such as flat panel displays), and light sources (e.g., liquid-crystal displaying backlights and illuminating light sources). Some of organic EL elements have already been developed for practical uses. Recently, in consideration of application and development of organic EL elements to such uses, an organic EL element having high efficiency, prolonged lifetime, and high brightness is expected.

It is considered that the efficiency of the organic EL element is mainly dominated by three of electrical-optical conversion efficiency, driving voltage, and light outcoupling efficiency. With regard to the electrical-optical conversion efficiency, it was reported that the organic EL element with the light emitting layer made of phosphorescent light emitting material can have external quantum efficiency greater than 20%. The external quantum efficiency of 20% is considered to be corresponding to internal quantum efficiency of about 100%. It is considered that the organic EL element having the electrical-optical conversion efficiency reaching a limiting value has been developed. In view of the driving voltage, an organic EL element which shows relatively high brightness in receipt of voltage higher by 10 to 20% than voltage corresponding to an energy gap of the light emitting layer has been developed. Consequently, it is expected that improvement of these two factors (electrical-optical conversion) are not so effective for an increase in the efficiency of the organic EL element.

Generally, the organic EL element has the light outcoupling efficiency in the range of about 20 to 30% (this value slightly changes depending on lighting patterns, and/or a layer structure between the anode and the cathode). This light outcoupling efficiency is not high. This low light outcoupling efficiency may be explained by the following consideration: materials used for light emitting portion and a vicinity thereof has characteristics such as a high refractive index and light absorption properties, and therefore the total reflection at the interfaces between materials with different refractive indices and absorption of light by materials may occur and this causes inhibition of effective propagation of light to the outside. Such low light outcoupling efficiency means 70 to 80% of the total amount of emitted light does not effectively contribute to light emission. Consequently, it is considered that improvement of the light outcoupling efficiency causes a great increase in the efficiency of the organic EL element.

In consideration of the above background, there is studied and developed actively to improve the light outcoupling efficiency. Especially, there have been many efforts to increase the amount of light which is emitted from the organic layer and reaches the substrate layer. For example, the organic layer has the refractive index of about 1.7, and a glass layer serving as the substrate has the refractive index of about 1.5. In this case, a loss caused by total reflection at the interface between the organic layer and the glass layer probably reaches about 50% of totally reflected light. The value of about 50% is calculated by use of point source approximation in consideration that the emitted light is expressed as an integration of three dimensional radiation of light from organic molecules. Unfortunately, the total reflection at the interface between the organic layer and the glass layer tends to cause a great loss. In view of this, it is possible to greatly improve the light outcoupling efficiency by decreasing the loss caused by the total reflection between the organic layer and the glass layer.

The most simple and effective approach for reducing the total reflection loss at the interface between the organic layer and the substrate is to decrease a difference between the refractive indices between the organic layer and the substrate. In this approach, two efforts are considered: (1) to decrease the refractive index of the organic layer and (2) to increase the refractive index of the substrate. With regard to the effort (1), available material is limited, and some of available material may cause great decreases in the light emission efficiency and lifetime. It is therefore now difficult to improve the light outcoupling efficiency in line with this effort (1). Meanwhile, with regard to the effort (2), various efforts have been examined in the past.

For example, document 1 (U.S. Pat. No. 7,053,547 B2) discloses that the substrate of the high refractive index glass can cause a great increase in the light outcoupling efficiency. However, the high refractive index glass is much more expensive than generally-used glass, and the high refractive index glass is impractical in view of the industrial availability. Additionally, the high refractive index glass generally contains various impurities (e.g., heavy metal). Thus, many of the high refractive index glass are fragile and have insufficient weatherproof properties.

Document 2 (U.S. Pat. No. 5,693,956 A) discloses another solution. In this document 2, to achieve the high light outcoupling efficiency, an organic EL element is formed on a plastic substrate with a refractive index higher than a refractive index of glass. In this case, the production cost of the device according to document 2 can be lowered than that of the device including the glass substrate. However, the plastic has good water permeability. Hence, the lifetime of the organic EL element is much shorter in the device according to document 2 than in the device including the glass substrate. Further, the surface of the plastic substrate easily suffers from scratches. Therefore, the weather resistance seems to be insufficient.

Document 3 (JP 2004-322489 A) discloses that, to prevent water passage, the gas barrier substrate of inorganic/organic material is disposed between the plastic substrate and the organic layer. However, the structure disclosed by this document does not have sufficient weather resistance. Further, the structure becomes complex and the production process becomes troublesome, and thus this structure has a disadvantage in the production cost thereof.

Document 4 (JP 2002-373777 A) discloses the structure in which the organic EL element on the film is perfectly enclosed by the glass or the gas barrier structure. However, this structure requires additional parts to make connection with electrodes. Hence, the structure becomes more complex and the production process becomes more troublesome. Further, the above structure is devoid of the light outcoupling structure, and therefore the sufficient improvement of the light outcoupling efficiency is not expected.

### SUMMARY OF INVENTION

In view of the above insufficiency, the present invention has aimed to propose a planar light emitting device which can reduce total reflection loss to improve a light outcoupling efficiency thereof and can have excellent water resistance and excellent weather resistance.

The planar light emitting device of the first aspect in accordance with the present invention includes an organic electroluminescence element, a formation substrate, a light outcoupling structure, a first moisture preventer, and a second moisture preventer. The organic electroluminescence element includes a first surface and a second surface which are opposite surfaces in a thickness direction of the organic electroluminescence element. The organic electroluminescence element is configured to emit light via the first surface. The formation substrate is of a resin material with a light transmissive property allowing light emitted from the organic electroluminescence element to pass therethrough. The formation substrate is adjacent to the first surface of the organic electroluminescence element. The light outcoupling structure is provided to the formation substrate and suppresses reflection of light emitted from the organic electroluminescence element at a surface of the formation substrate. The first moisture preventer has a moisture proof property. The first moisture preventer is over the second surface of the organic electroluminescence element to cover the organic electroluminescence element. The second moisture preventer has a moisture proof property, and covers the formation substrate to prevent moisture from passing through the formation substrate and reaching the first surface of the organic electroluminescence element. The second moisture preventer includes an overlap which overlaps the first surface in the thickness direction of the organic electroluminescence element. The overlap is of material with a light transmissive property allowing light emitted from the organic electroluminescence element to pass therethrough.

According to the planar light emitting device of the second aspect in accordance with the present invention, in addition to the first aspect, the second moisture preventer includes a protection substrate serving as the overlap. The protection substrate has a light transmissive property allowing light emitted from the organic electroluminescence element to pass therethrough, and has a moisture proof property. The protection substrate is on an opposite side of the formation substrate from the organic electroluminescence element.

According to the planar light emitting device of the third aspect in accordance with the present invention, in addition to the second aspect, the first moisture preventer does not cover a side surface of the formation substrate.

According to the planar light emitting device of the fourth aspect in accordance with the present invention, in addition to the third aspect, the second moisture preventer further includes a coating layer. The coating layer has a moisture proof property, and covers the side surface of the formation substrate.

According to the planar light emitting device of the fifth aspect in accordance with the present invention, in addition to the fourth aspect, the coating layer is of material containing desiccant.

According to the planar light emitting device of the sixth aspect in accordance with the present invention, in addition to the fourth or fifth aspect, the planar light emitting device further includes an electrode connector for power supply to the organic electroluminescence element. The electrode connector is in the coating layer.

According to the planar light emitting device of the seventh aspect in accordance with the present invention, in addition to the second aspect, the first moisture preventer cooperates with the protection substrate of the second moisture preventer to form a housing which accommodates the organic electroluminescence element to protect the organic electroluminescence element from moisture.

According to the planar light emitting device of the eighth aspect in accordance with the present invention, in addition to any one of the second to seventh aspects, the light outcoupling structure is a recessed and protruded structure provided to the surface of the formation substrate.

According to the planar light emitting device of the ninth aspect in accordance with the present invention, in addition to the eighth aspect, the light outcoupling structure has a refractive index higher than a refractive index of the protection substrate.

According to the planar light emitting device of the tenth aspect in accordance with the present invention, in addition to the eighth or ninth aspect, the light outcoupling structure has a refractive index higher than a refractive index of the formation substrate.

According to the planar light emitting device of the eleventh aspect in accordance with the present invention, in addition to any one of the second to seventh aspects, the light outcoupling structure is of a different material from the formation substrate.

According to the planar light emitting device of the twelfth aspect in accordance with the present invention, in addition to the eleventh aspect, the light outcoupling structure is between the formation substrate and the protection substrate.

According to the planar light emitting device of the thirteenth aspect in accordance with the present invention, in addition to the eleventh aspect, the light outcoupling structure is between the formation substrate and the organic electroluminescence element.

According to the planar light emitting device of the fourteenth aspect in accordance with the present invention, in addition to any one of the eleventh to thirteenth aspects, the light outcoupling structure is a light diffusion layer of a mixture of light diffusion particles dispersed in a matrix with a refractive index higher than a refractive index of the protection substrate. The light diffusion particles have a refractive index different from the refractive index of the matrix.

According to the planar light emitting device of the fifteenth aspect in accordance with the present invention, in addition to any one of the eleventh to thirteenth aspects, the light outcoupling structure is a light diffusion layer of a mixture of light diffusion particles dispersed in a matrix with a refractive index higher than a refractive index of the formation substrate. The light diffusion particles have a refractive index different from the refractive index of the matrix.

According to the planar light emitting device of the sixteenth aspect in accordance with the present invention, in addition to any one of the eleventh to thirteenth aspects, the light outcoupling structure has a refractive index lower than a refractive index of the formation substrate.

According to the planar light emitting device of the seventeenth aspect in accordance with the present invention, in addition to any one of the eleventh to thirteenth, and sixteenth aspects, the light outcoupling structure has a refractive index lower than a refractive index of the protection substrate.

According to the planar light emitting device of the eighteenth aspect in accordance with the present invention, in addition to any one of the second to seventeenth aspects, the formation substrate has a refractive index higher than a refractive index of the protection substrate.

According to the planar light emitting device of the ninetieth aspect in accordance with the present invention, in addition to any one of the second to eighteenth aspects, the protection substrate is of glass.

According to the planar light emitting device of the twentieth aspect in accordance with the present invention, in addition to the first aspect, the second moisture preventer includes a gas barrier layer serving as the overlap. The gas barrier layer has a light transmissive property allowing light emitted from the organic electroluminescence element to pass therethrough, and has a moisture proof property. The gas barrier layer is between the formation substrate and the organic electroluminescence element.

According to the planar light emitting device of the twenty-first aspect in accordance with the present invention, in addition to the twentieth aspect, the gas barrier layer satisfies a condition that an average of differences between refractive indices of the gas barrier layer and the formation substrate with regard to light rays in a visible range is not greater than 0.05.

According to the planar light emitting device of the twenty-second aspect in accordance with the present invention, in addition to the twentieth or twenty-first aspect, the second moisture preventer includes a protection substrate serving as the overlap. The protection substrate has a light transmissive property allowing light emitted from the organic electroluminescence element to pass therethrough, and has a moisture proof property. The protection substrate is on an opposite side of the formation substrate from the organic electroluminescence element.

According to the planar light emitting device of the twenty-third aspect in accordance with the present invention, in addition to the twenty-second aspect, the protection substrate is attached to the formation substrate in a removable fashion.

According to the planar light emitting device of the twenty-fourth aspect in accordance with the present invention, in addition to any one of the first to twenty-third aspects, the organic electroluminescence element includes a light emitting layer, and an electrode between the light emitting layer and the formation substrate. The electrode includes a metal thin film with such a thickness as to allow passage of light emitted from the organic electroluminescence element.

According to the planar light emitting device of the twenty-fifth aspect in accordance with the present invention, in addition to the twenty-fourth aspect, the metal thin film is of Ag or an Ag alloy.

### BRIEF DESCRIPTION OF THE DRAWINGS

FIG. 1 is a section view illustrating the planar light emitting device of the first embodiment,

FIG. 2 is a section view illustrating the planar light emitting device of the first embodiment,

FIG. 3 is a section view illustrating a modification of the planar light emitting device of the first embodiment,

FIG. 4 is a schematic diagram illustrating light outcoupling by a light outcoupling structure,

FIG. 5 is a schematic diagram illustrating light outcoupling by the light outcoupling structure,

FIG. 6 is a schematic diagram illustrating light outcoupling by the light outcoupling structure,

FIG. 7 is a graph showing a relation between a film formation temperature and a specific resistance of an ITO film,

FIG. 8 is a section view illustrating the planar light emitting device of the second embodiment,

FIG. 9 is a section view illustrating a modification of the planar light emitting device of the second embodiment, and

FIG. 10 is a section view illustrating the planar light emitting device of the third embodiment.

### DESCRIPTION OF EMBODIMENTS

### First Embodiment

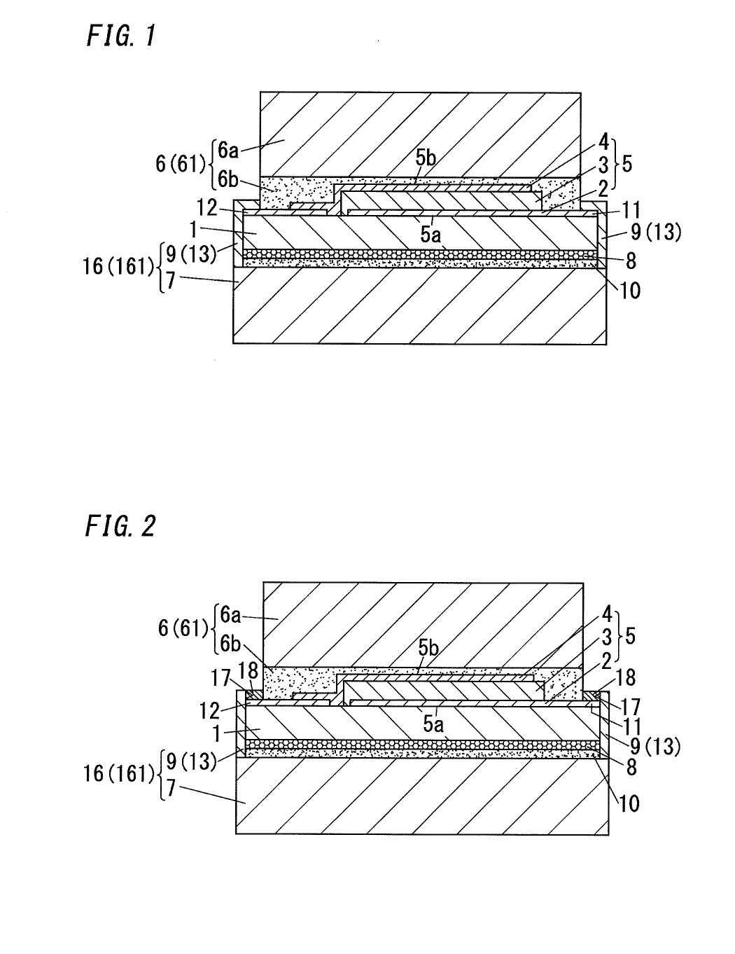

FIG. 1 shows an example of a planar light emitting device of the first embodiment. In this planar light emitting device, an organic electroluminescence element 5 (organic EL element 5) is formed on a surface of a formation substrate 1 with a light transmissive property. The organic electroluminescence element 5 includes a first electrode 2, a light emitting layer 3, and a second electrode 4 which are arranged in this order from the formation substrate 1. The first electrode 2 has a light transmissive property.

In other words, the planar light emitting device of the present embodiment includes an organic EL element 5 and a formation substrate 1. The organic EL element 5 includes a first surface (lower surface in FIG. 1) 5a and a second surface (upper surface in FIG. 1) 5b which are opposite surfaces in a thickness direction (upward and downward direction in FIG. 1) thereof. The organic EL element 5 is configured to emit light via the first surface 5a. The formation substrate 1 is placed close to the first surface 5a of the organic EL element 5.

The formation substrate 1 of the planar light emitting device is of resin. For example, the formation substrate 1 is made of a resin material with a light transmissive property of allowing light emitted from the organic EL element to pass therethrough. This causes a decrease in a difference between refractive indices of the organic EL element 5 and the formation substrate 1, and therefore a total reflection loss at an interface between an organic layer and a substrate is reduced.

The formation substrate 1 serves as a substrate for forming the organic EL element 5 with a stacking manner. Accordingly, it is preferable that the formation substrate 1 has a higher heat resistance. The formation substrate 1 may be a plastic substrate. Additionally, the formation substrate 1 may be a rigid substrate. Alternatively, the formation substrate 1 may be a flexible sheet or a flexible film. Besides, to reduce the total reflection loss, a refractive index of the formation substrate 1 is preferably 1.6 or more, and is more preferably 1.8 or more.

Material of the formation substrate 1 preferably has a refractive index higher than a refractive index of normal glass (a refractive index is about 1.5), and need not fulfill other conditions except it has such a refractive index. For example, it is possible to use a PET substrate which is a representative plastic material with a refractive index higher than a refractive index of glass. PET (polyethylene terephthalate) is one of the most common materials, and is a very inexpensive and safe material. Alternatively, for example, in view of a high refractive index and a high heat resistance, it is effective to use a substrate of material such as PEN (polyethylene naphthalate), PES (polyethersulfone), and PC (polycarbonate).

The organic EL element 5 includes: the first surface (lower surface in FIG. 1) 5a; and the second surface (upper surface in FIG. 1) 5b which is an opposite surface of the organic EL element 5 from the first surface 5a in the thickness direction (upward and downward direction in FIG. 1) of the organic EL element 5. The organic EL element 5 is configured to emit light via the first surface 5a.

The organic EL element 5 includes: the first electrode 2; the light emitting layer 3 provided on the first electrode 2; and the second electrode 4 provided on the light emitting layer 3. In the organic EL element 5, the first electrode 2 may be a light transmissive (transparent or translucent) electrode, and the second electrode 4 may be a light reflective electrode. In this case, light produced by the light emitting layer 3 is emitted outside via the first electrode 2. In brief, the first surface 5a is an opposite surface (lower surface in FIG. 1) of the first electrode 2 from the light emitting layer 3. Similarly, the second surface 5b is an opposite surface (upper surface in FIG. 1) of the second electrode 4 from the light emitting layer 3.

Generally, the first electrode 2 serves as an anode, and the second electrode 4 serves as a cathode. However, the first electrode 2 may serve as a cathode, and the second electrode 4 may serve as an anode. The light emitting layer 3 is a layer allowing recombination of holes injected from the anode (first electrode 2) and electrons injected from the cathode (second electrode 4) to produce light. The light emitting layer 3 includes layers such as a hole injection layer, a hole transport layer, an electron transport layer, and an electron injection layer, in addition to a light emitting material layer containing a light emitting material. Additionally, the light emitting layer 3 may include one or more layers appropriately selected from interlayers for assisting production of light and transport of electrons, and a functional layer.

The refractive index of the first electrode 2 may fall within an approximate range of 1.8 to 2, for example, but is not limited to this range. Besides, to reduce the total reflection loss at the interface between the organic layer and the substrate, it is preferable that a difference between the refractive indices between the first electrode 2 and the formation substrate 1 be smaller.

A first protector 61 is provided on a surface of the formation substrate 1 close to the organic EL element 5 to encapsulate the organic EL element 5 by accommodating the organic EL element 5. The first protector 61 encapsulates the organic EL element 5 to protect the organic EL element 5. The first protector is made of an appropriate material.

In the present embodiment, the first protector 61 is constituted by an encapsulation substrate 6a made of a glass substrate, and an encapsulation member 6b made of material (e.g., resin) with a moisture proof property. In other words, the first protector 61 is made of low moisture permeable material. Accordingly, it is possible to suppress intrusion of moisture to an inside of the element through the second electrode 4.

The first protector 61 has a moisture proof property, and is over the second surface 5b of the organic electroluminescence element 5 to cover the organic electroluminescence element 5. The first protector 61 is formed to not cover a side surface of the formation substrate 1. The first protector 61 is formed to expose the outer peripheral surface (surrounding surface) of the formation substrate 1. In other words, the first protector 61 is formed to not enclose the formation substrate 1 in a plane across (in the present embodiment, perpendicular to) the thickness direction of the organic EL element 5.

In concrete, for example, the encapsulation substrate 6a may be made of material such as glass and metal. In this case, the encapsulation substrate 6a can prevent outside moisture from passing therethrough.

The encapsulation member 6b may be of resin material with low moisture permeability, or may contain a moisture prevention agent. In this case, it is possible to prevent outside moisture from passing through the encapsulation member 6b. The encapsulation member 6b may include an edge part (peripheral part) exposed outside, and an inner part. The edge part may be of a material with a moisture proof property at least, and the inner part may be of an encapsulation resin. In this case, it is possible to prevent the intrusion of moisture and improve specific properties of the encapsulation member 6b such as adhesiveness and filling properties.

The first protector 61 is placed so as not to cover an edge portion (edge and its vicinity) of the formation substrate 1 in a plan view. For example, when the planar light emitting device is viewed in a direction normal to the formation substrate 1, the periphery of the first protector 61 is determined such that the edge portion of the formation substrate 1 is outside the first protector 61. The edge portion of the formation substrate 1 outside the first protector 61 may be an exposed region when the second protector 9 is not provided. The edge portion of the formation substrate 1 outside the first protector 61 may extend along an entire enclosing boundary of the formation substrate 1 with a planar shape.

There are an electrode extension part 11 and an electrode conduction part 12 on the edge of the formation substrate 1. The electrode extension part 11 is a part extended from the first electrode 2. The electrode conduction part 12 is electrically connected to the second electrode 4. The first protector 61 does not cover the edge of the formation substrate 1. Hence, the electrode extension part 11 and the electrode conduction part 12 can be disposed outside the encapsulation region. It is possible to supply power to the first electrode 2 and the second electrode 4.

The planar light emitting device of the present embodiment includes a second moisture preventer 16 (161). The second moisture preventer 161 has a moisture proof property, and covers the formation substrate 1 to prevent moisture from passing through the formation substrate 1 and reaching the first surface 5a of the organic EL element 5.

The second moisture preventer 161 includes an overlap which overlaps the first surface 5a in the thickness direction of the organic EL element 5. The overlap is of material with a light transmissive property allowing light emitted from the organic EL element to pass therethrough. In other words, the overlap is configured to allow passage of light emitted from the organic EL element.

In the present embodiment, the second moisture preventer 161 is constituted by a protection substrate 7 and a second protector 9.

The protection substrate 7 is provided on a surface of the formation substrate 1 which is far from the organic EL element 5. In other words, the protection substrate 7 is on an opposite side of the formation substrate 1 from the organic EL element 5.

The protection substrate 7 is of an appropriate material with a light transmissive property and low moisture permeability. In other words, the protection substrate 7 has a moisture proof property, and has a light transmissive property allowing light emitted from the organic EL element to pass therethrough. In the present embodiment, the protection substrate 7 serves as the overlap of the second moisture preventer 161.

The protection substrate 7 has the moisture proof property, and therefore it is possible to prevent intrusion of moisture into an inside of the element from an outside of the first electrode 2. For example, when the protection substrate 7 is of material such as glass and a moisture proof transparent resin, the protection substrate 7 can prevent outside moisture from passing through the protection substrate 7, and allows emission of light produced by the organic EL element 5 to the outside the protection substrate 7. In view of improvement of the moisture proof property, it is preferable that the protection substrate 7 may be of glass. A refractive index of the protection substrate 7 may be about 1.5, but is not limited to this.

The protection substrate 7 may be greater in size than the formation substrate 1. In other words, the periphery of the protection substrate 7 is determined such that a whole of the formation substrate 1 is on the surface of the protection substrate 7 and the edge of the formation substrate 1 is inside the protection substrate 7. According to this structure, a coating layer 13 described below can easily cover the formation substrate 1.

It is preferable that the formation substrate 1 have a refractive index higher than the refractive index of the protection substrate 7. Accordingly, the total reflection loss can be reduced efficiently. In this case, the refractive index is the highest for the formation substrate 1, followed by the protection substrate 7 and then the outside (the atmosphere with a refractive index of 1). As a result of that, a difference in refractive index between the element and the outside can become smaller towards the outside than at the inside of the element. Therefore, the total reflection can be suppressed and the light outcoupling efficiency can be improved. Such a structure is advantageous to a waveguiding mode for the thin planar light emitting device.

There is a light outcoupling structure 8 between the protection substrate 7 and the formation substrate 1. The light outcoupling structure 8 suppresses reflection of light emitted from the organic EL element 5. In other words, the light outcoupling structure 8 is provided to the formation substrate 1 and is configured to suppress reflection of light emitted from the organic EL element 5 at the surface of the formation substrate 1.

As described below, the light outcoupling structure 8 may be formed by shaping the surface of the formation substrate 1 into a structure giving a high light outcoupling efficiency, or forming a layer giving a high light outcoupling efficiency. This layer has such characteristics that differences between refractive indices of layers are reduced, or light directions are changed inside the layers.

It is preferable that the protection substrate 7 be bonded to the formation substrate 1 with a bonding layer 10. The bonding layer 10 is of an appropriate adhesive resin material. When the light outcoupling structure 8 is of resin, the light outcoupling structure 8 may serve as the bonding layer 10.

In this planar light emitting device, the second protector 9 is provided to the formation substrate 1. The second protector 9 prevents intrusion of moisture into the organic EL element 5 through the formation substrate 1.

When the formation substrate 1 is considered as a path (moisture permeable path), the second protector 9 serves to interrupt connection between the outside and the inside (the organic EL element 5). Such a path can be blocked at at least one of a boundary between the outside and the path and a boundary between the inside (the organic EL element 5) and the path. The second protector 9 may have at least one of an outside block structure and an inside block structure. The outside block structure covers at least one part of the formation substrate 1 to prevent exposure of the formation substrate 1 to the outside. The inside block structure covers at least one part of the formation substrate 1 to prevent contact between the formation substrate 1 and the organic EL element 5.

In the embodiment shown in FIG. 1, the second protector 9 has the outside block structure. This second protector 9 serves as the coating layer 13 covering part of the formation substrate 1 which is outside the first protector 61. In other words, the coating layer 13 covers the side surface of the formation substrate 1. Especially, the coating layer 13 covers the entire outer peripheral surface of the formation substrate 1. In other words, the coating layer 13 is formed to enclose the formation substrate 1 in a plane across (in the present embodiment, perpendicular to) the thickness direction of the organic EL element 5.

When the organic EL element 5 is encapsulated with the first protector 61 as described above, it is necessary to secure paths for supply electricity to the organic EL element 5 from the outside. Hence, part of the edge of the formation substrate 1 on which the electrode extension part 11 and the electrode conduction part 12 are provided is placed outside the first protector 61. In this case, when the formation substrate 1 is of resin, this formation substrate 1 is likely to act as an intrusion path of moisture unfortunately. This may lead a decrease in the reliability of the element caused by the moisture intrusion. In this case, the intrusion path of moisture is mainly constituted by the formation substrate 1 of the resin, an interface between the electrode extension part 11 and the formation substrate 1, and an interface between the electrode conduction part 12 and the formation substrate 1.

The coating layer 13 is provided to cover the part of the formation substrate 1 outside the first protector 61 and serves as the second protector 9. Hence, the edge of the formation substrate 1, the electrode extension part 11, and the electrode conduction part 12 are covered with the second protector 9, and therefore the moisture permeable path is blocked. Accordingly, it is possible to prevent intrusion of moisture through the formation substrate 1, and thus reduce deterioration in the element.

The coating layer 13 may cross an edge line (corner) of the surface of the formation substrate 1. In this case, the entire outer surface (the upper surface and the side surface) of the formation substrate 1 can be covered.

It is preferable that the coating layer 13 is in contact with the protection substrate 7. In this case, the entire side surface of the formation substrate 1 is covered and thus exposure of the side surface of the formation substrate 1 to the outside can be prevented.

It is preferable that the coating layer 13 is in contact with the first protector 61. In this case, with regard to an interface area between the first protector 6 and the formation substrate 1, exposure of the side surface of the formation substrate 1 to the outside can be prevented.

This first protector 61 can be obtained by covering a boundary region between the formation substrate 1 and one of the coating layer 13 and the first protector 61 which is formed in advance, with the other of the coating layer 13 and the first protector 61 which is formed subsequently.

For example, the first protector 61 is formed and thereafter the coating layer 13 is formed to overlap the first protector 61. In this case, as shown in FIG. 1, the side surface of the first protector 61 close to the formation substrate 1 is covered with the coating layer 13 and thus the formation substrate 1 is covered. Alternatively, when the coating layer 13 is formed in advance, the first protector 61 is formed on the surface of this coating layer 13. Thus, it is possible to prevent exposure of the surface of the formation substrate 1 to the outside.

According to the present embodiment, the whole of the organic EL element 5 is enclosed by the protection substrate 7, the first protector 61, and the second protector 9, and thus the organic EL element 5 is encapsulated and protected. The protection substrate 7, the first protector 61, and the second protector 9 have the high moisture proof properties. Therefore, it is possible to prevent intrusion of moisture into the organic EL element 5 efficiently.

The coating layer 13 constituting the second protector 9 may be of an inorganic material or an appropriate resin with low moisture permeability. Especially, the coating layer 13 of an inorganic material can have a higher moisture proof property. The coating layer 13 of such a resin can have high adhesiveness. To prevent a short circuit, it is preferable that the second protector 9 be of a material with low electrical conductivity (high electrically insulating property).

The coating layer 13 may be selected from an inorganic film of SiN, a resin film with low moisture permeability, and a composite film of at least one of these films and a plating film. The inorganic material may include SiO₂ and TiO₂. The inorganic film may be formed with sputtering. The resin film may be formed with printing. When the plating film is formed, it is preferable that the plating film cause no short circuit and be electrically connected to the corresponding electrode. For example, the plating films are formed on regions corresponding to the electrode extension part 11 and the electrode conduction part 12, and the resin film is formed on the other regions. In this case, electrical connection and block of the moisture permeable path can be made efficiently.

It is preferable that the coating layer 13 contain desiccant. The desiccant can improve the moisture proof property of the coating layer 13, and therefore it is possible to improve the effect of preventing moisture from reaching the organic EL element 5. Especially, when the coating layer 13 is of the resin, unfortunately moisture is more likely to intrude through the coating layer 13. However, the coating layer 13 containing the desiccant can suppress intrusion of moisture efficiently.

It is preferable that the coating layer 13 include at least one electrode connector 18 (see FIG. 2). The electrode connector 18 is used for power supply to the organic EL element 5. The coating layer 13 may include the electrode connector 18 connected to the electrode extension part 11 and the electrode connector 18 connected to the electrode conduction part 12. Provision of the electrode connector 18 can facilitate application of a voltage to the organic EL element 5. The electrode connector 18 may be of an electrically conductive material such as metal. The electrode connector 18 may be formed before formation of the coating layer 13 or after formation of the coating layer 13. When the electrode connector 18 is formed before formation of the coating layer 13, the coating layer 13 may be formed so as not to cover at least one part of the electrode connector. Alternatively, when the electrode connector 18 is formed after formation of the coating layer 13 as shown in FIG. 2, a through hole 17 is formed in the coating layer 13 and then the electrode connector 18 is formed inside the through hole 17. It is preferable that the coating layer 13 include a portion of the electrically conductive material like the plating film described above and this portion serve as the electrode connector 18.

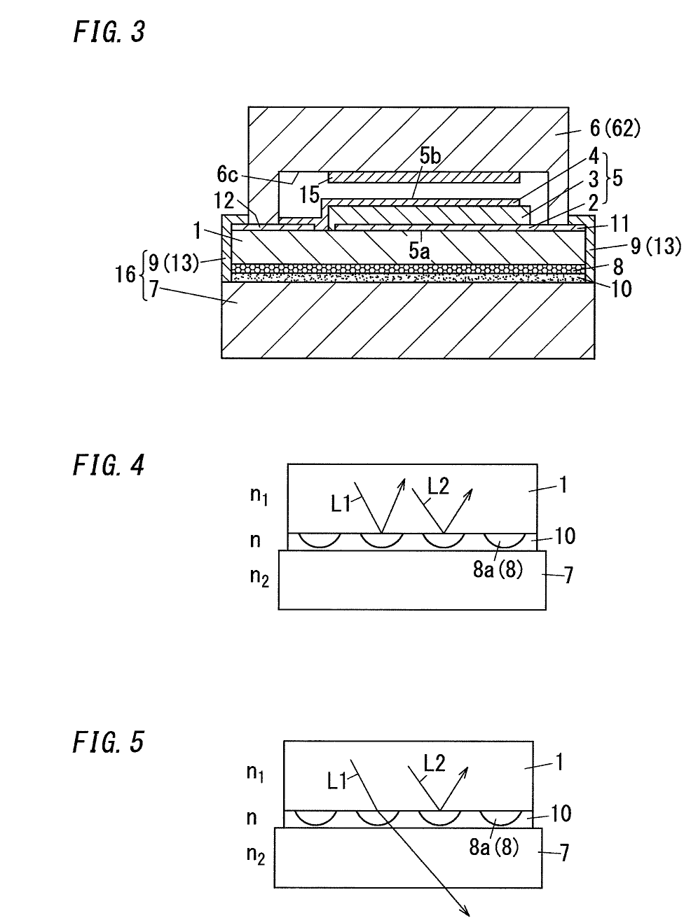

FIG. 3 shows a planar light emitting device according to another example (modification). This planar light emitting device is the same as the embodiment shown in FIG. 1 except for the first protector 6 (62).

In the embodiment shown in FIG. 3, the first protector 62 cooperates with the formation substrate 1 to form a housing for enclosing the organic EL element 5. The first protector 62 is provided with a recess 6c for receiving the organic EL element 5. This recess 6c defines an inner space of the housing. The recess 6c may be obtained by excavating a base for the first protector 62 with etching. Preferably, the first protector 62 is of glass. The first protector 62 is bonded to the formation substrate 1 such that the organic EL element 5 is inside the recess 6c. Thus, the first protector 62 can encapsulate the organic EL element 5.

In the embodiment shown in FIG. 3, it is preferable that a water absorption member 15 be attached to a surface (inner bottom surface) of the recess 6c. Even when moisture intrudes into the housing, the water absorption member 15 absorbs such moisture, thereby suppressing intrusion of moisture into the organic EL element 5. For example, the water absorption member 15 may be a getter material containing water absorbing inorganic salt (e.g., calcium oxide).

The first protector 62 may be bonded to the formation substrate 1 with an adhesive resin. Alternatively, the first protector 62 may be bonded to the formation substrate 1 with the second protector 9 (coating layer 13) which is made of a material for the second protector 9 instead of the adhesive resin or together with the adhesive resin to cover the periphery of the first protector 62. In this case, a boundary region between the formation substrate 1 and the first protector 62 is covered with the second protector 9 and thus an effect of suppressing moisture intrusion can be improved.

Hereinafter, the light outcoupling structure 8 is described in more detail.

To improve the light outcoupling efficiency of the planar light emitting device, the light outcoupling structure 8 is important. When the light outcoupling structure 8 is not provided, it is difficult to improve the light outcoupling efficiency.

Generally, the refractive indices of the organic EL element 5, the formation substrate 1 and the protection substrate 7 are greater than the refractive index of the atmosphere which is the outside to which light is emitted. For example, the generally-used organic layer has the refractive index n of about 1.7, and the glass has the refractive index n of about 1.5. In this case, when light travels from a high refractive index layer toward a low refractive index layer, the total reflection of such light may occur at an interface between the high refractive index layer and the low refractive index layer. Especially, when the light strikes the interface at an angle not less than the total reflection angle (i.e., a critical angle), this light is reflected. The reflected light is multiply-reflected inside the organic layer or the substrate, and is attenuated. Thus, this light is not emitted outside. Hence, the light outcoupling efficiency may be decreased.

Even when light strikes an interface at an angle not greater than the total reflection angle, an interface between substances with different refractive indices causes Fresnel reflection and such light is also reflected. Therefore, the light outcoupling efficiency may be more decreased.

In view of the above, to improve the light outcoupling efficiency to the outside, the light outcoupling structure 8 is provided on a light exit surface of the formation substrate 1.

A preferable example of the light outcoupling structure 8 is a recessed and protruded structure 8a on the surface of the formation substrate 1 as shown in FIGS. 4 to 7. Provision of the recessed and protruded structure 8a to the surface of the formation substrate 1 can cause an increase in the light outcoupling efficiency to the outside. The recessed and protruded structure 8a causes a variation in an incident angle of light. Hence, light rays are scattered and therefore light rays with angles equal to or more than the total reflection angle can be emitted outside. For this reason, light can travel from the formation substrate 1 to the protection substrate 7.

It is preferable that the recessed and protruded structure 8a have a two-dimensional periodic structure. When light produced by the light emitting layer 3 has a wavelength in the range of 300 to 800 nm, the two-dimensional periodic structure preferably has a period P in the range of one fourth to ten times of λ. Besides, λ is a wavelength of light in a medium (obtained by dividing a wavelength of light in vacuum by a refractive index of the medium).

For example, when the period P is in the range of 5λ to 10λ, a geometrical optics effect (enlargement of an area of the surface which light strikes at an angle less than the total reflection angle) causes an increase in the light outcoupling efficiency.

When the period P is in the range of λ to 5λ, light striking the surface at an angle not less than the total reflection angle can be emitted outside as diffraction light. Consequently, the light outcoupling efficiency is improved.

When the period P is in the range of λ/4 to λ, an effective refractive index at a portion around the recessed and protruded structure 8a is decreased with an increase in distance between the portion and the organic EL element 5. This is equivalent to interposing, between the formation substrate 1 and the protection substrate 7, a thin layer having a refractive index between the refractive index of the medium of the recessed and protruded structure 8a and the refractive index of the protection substrate 7 (or, the medium of the space between the recessed and protruded structure 8a and the protection substrate 7). Consequently, it is possible to suppress the Fresnel reflection.

In brief, with selecting the period P from the range of λ/4 to 10λ, it is possible to suppress the reflection (total reflection and/or Fresnel reflection), and therefore can improve the light outcoupling efficiency with regard to light from the organic EL element 5. Note that, the improvement of the light outcoupling efficiency caused by the geometrical optics effect can be obtained unless the period P is greater than an upper limit. For example, the upper limit is 1000λ.

The recessed and protruded structure 8a does not necessarily have a periodic structure such as the two-dimensional periodic structure. For example, the recessed and protruded structure 8a may have a recessed and protruded structure in which sizes of recesses and/or protrusions are randomly determined, and an aperiodic recessed and protruded structure. Also in this instance, it is possible to improve the light outcoupling efficiency. When the recessed and protruded structure 8a is a combination of recessed and protruded structural parts different from each other in size (e.g., the recessed and protruded structure 8a includes the recessed and protruded structural part with the period P of 1λ and the recessed and protruded structural part with the period P equal to or more than 5λ), the light outcoupling effect caused by the recessed and protruded structural part having the highest occupancy in the recessed and protruded structure 8a is dominant.

It is preferable that the light outcoupling structure 8 constituted by the recessed and protruded structure 8a has the refractive index higher than the refractive index of the protection substrate 7. Additionally, it is preferable that the light outcoupling structure 8 constituted by the recessed and protruded structure 8a has the refractive index higher than the refractive index of the formation substrate 1.

In the following, to analyze the reflection of light, the refractive index of the recessed and protruded structure 8a is represented by “n”, the refractive index of the formation substrate 1 is represented by “n1”, and the refractive index of the protection substrate 7 is represented by “n2”. FIGS. 4 to 7 show schematic diagrams of the reflection of light by the recessed and protruded structure 8a.

As described above, it is preferable that the formation substrate 1 has the refractive index higher than the refractive index of the protection substrate 7. In brief, the refractive index of the protection substrate is lower than the refractive index of the formation substrate. In short, the relation of n2<n1 is fulfilled. When the recessed and protruded structure 8a has the refractive index lower than the refractive index of the protection substrate, the refractive index of the recessed and protruded structure is the lowest, followed by the refractive index of the protection substrate, and then the refractive index of the formation substrate. In short, the relation of n<n2<n1 is fulfilled.

In this case, as shown in FIG. 4, the loss due to the total internal reflection at the interface between the recessed and protruded structure 8a and the formation substrate 1 becomes greater. FIG. 4 shows that light rays L1 and L2 are reflected at the interface. The light ray L1 strikes the interface at a certain angle, and the light ray L2 strikes the interface at an angle greater than the certain angle. As described above, the total reflection occurs between the formation substrate 1 and the recessed and protruded structure 8a, and thus an amount of light emitted outside is reduced.

For the above reason, it is preferable that the recessed and protruded structure 8a has the refractive index higher than the refractive index of the protection substrate 7. When the recessed and protruded structure 8a has the refractive index higher than the refractive index of the protection substrate 7, it is considered that the refractive index of the recessed and protruded structure 8a may be between the refractive indices of the protection substrate 7 and the formation substrate 1 in the first case. In this case, the refractive index of the protection substrate is the lowest, followed by the refractive index of the recessed and protruded structure, and then the refractive index of the formation substrate. In short, the relation of n2<n<n1 is fulfilled.

In this case, as shown in FIG. 5, a critical angle for the interface between the recessed and protruded structure 8a and the formation substrate 1 becomes greater and thus the amount of light totally reflected is reduced. As shown in FIG. 5, the light ray L2 striking the interface at the greater angle is totally reflected. Whereas, the light ray L1 striking the interface at the relatively small angle is not totally reflected. Hence, the light ray L1 passes through the interface and then travels to the outside of the protection substrate 7. The total internal reflection between the formation substrate 1 and the recessed and protruded structure 8a is suppressed, and thus the light outcoupling efficiency is improved. In this condition of the refractive indices, the totally reflected light such as the light ray L2 is still present.

For the above reason, it is further preferable that the recessed and protruded structure 8a has the refractive index higher than the refractive index of the formation substrate 1. In this case, the refractive index of the protection substrate is the lowest, followed by the refractive index of the formation substrate and then the refractive index of the recessed and protruded structure. In short, the relation of n2<n1<n is fulfilled.

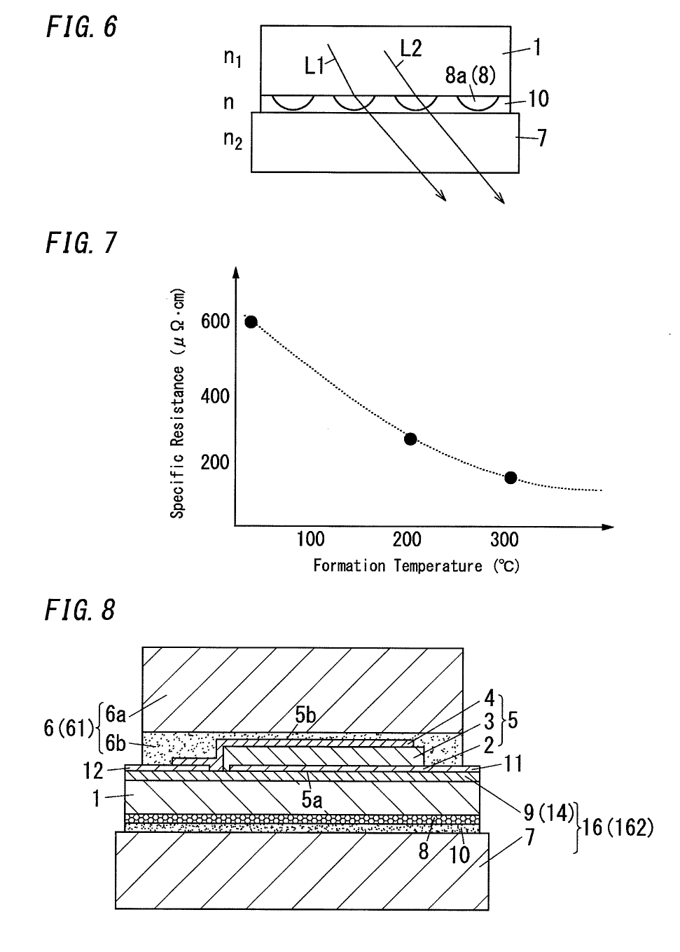

In this case, as shown in FIG. 6, the critical angle for the interface between the recessed and protruded structure 8a and the formation substrate 1 does not exist, and thus the light totally reflected disappears. As shown in FIG. 6, not only the light ray L1 striking the interface at the smaller angle but also the light ray L2 striking the interface at the larger angle is not totally reflected, but thus passes through the interface and then travels to the outside of the protection substrate 7. Hence, the total internal reflection between the formation substrate 1 and the recessed and protruded structure 8a disappears, and thus the light outcoupling efficiency is improved.

A difference in height between the protruded part and the recessed part of the recessed and protruded structure 8a is not limited to a particular one, but may be preferably in the range of 500 to 50000 nm in consideration for the design of the element and the light outcoupling efficiency. In a case where the difference in height between the protruded part and the recessed part is relatively small (is not greater than 3000 nm), diffraction is more effective than refraction. In a case where the difference in height between the protruded part and the recessed part is relatively large (is not less than 3000 nm), refraction is more effective than diffraction. In both cases, light is diffused and thus the loss caused by the total reflection can be suppressed. In a region where the diffraction is dominant, it is necessary to consider wavelength dependence of light. For this reason, an additional structure for reducing a color difference depending on a view angle may be provided outside the protection substrate 7.

The recessed and protruded structure 8a may be directly provided to the formation substrate 1 by shaping the formation substrate 1 itself. Alternatively, the recessed and protruded structure 8a may be provided to the formation substrate 1 by attaching an additional member to the formation substrate 1. In summary, the light outcoupling structure 8 may be formed of a material different from the material of the formation substrate 1.

For example, the recessed and protruded structure 8a may be provided to the formation substrate 1 by attaching a light diffusion sheet having a recessed and protruded structural part to the formation substrate 1. The light diffusion sheet may be a prism sheet or a light diffusion sheet. Alternatively, the recessed and protruded structure 8a may be formed in the surface of the formation substrate 1 for the light exit by transferring the recessed and protruded structural part to the formation substrate 1 by means of imprint lithography (nano-imprint lithography). When the formation substrate 1 is formed by means of injection molding, the recessed and protruded structural part may be provided directly to the formation substrate 1 by use of an appropriate mold tool.

The following brief explanation is made to a process of forming the recessed and protruded structure 8a by use of imprint lithography.

First, a layer is formed on the surface of the formation substrate 1 with appropriate methods such as spin coating and slit coating. This layer is used as a base for the recessed and protruded structure 8 and is of a transparent material having a high refractive index (e.g., thermostat resin containing nano-particles of TiO₂). The formation substrate 1 may be a PET substrate or a PEN substrate.

Thereafter, pre-baking is conducted to form a transfer layer (layer receiving the recessed and protruded structural part).

Next, a mold with a recessed and protruded pattern corresponding to the shape of the recessed and protruded structure 8a is pressed on the transfer layer. The mold may be an Ni mold or an Si mold patterned to have fine protrusions of height of 1 μm arranged in a two-dimensional array manner at a period of 2 μm. For example, the fine protrusion has a spindle shape (e.g., a square pyramid shape, a circular cone shape, a hemispherical shape, and a circular cylindrical shape).

Thereafter, the transfer layer which is modified by the mold is cured and then the mold is separated. Thus, the recessed and protruded pattern is transferred, and the recessed and protruded structure 8a is formed. Note that, curing may be accomplished by heat or light.

The imprint lithography may be thermal imprint lithography (thermal nano-imprint lithography) in which thermostat resin is used as the transparent material of the transfer layer as described above.

In the thermal imprint lithography, the mold is directly pressed against the surface of the formation substrate 1 and subsequently the formation substrate 1 is heated via the mold so as to modify part of the formation substrate 1 to form the recessed and protruded structure 8a. Thereafter, the mold is separated from the recessed and protruded structure 8a.

The imprint lithography is not limited to the thermal imprint lithography but may be optical imprint lithography (optical nano-imprint lithography) in which photo curable resin is used as the material of the transfer layer. In this case, the transfer layer of a photo curable resin with low viscosity is modified by use of the mold and then is cured by irradiating the transfer layer with ultraviolet light. Thereafter, the mold is separated from the cured transfer layer.

When the formation substrate 1 is incapable of transmitting ultraviolet light (e.g., a PEN substrate), a resin mold of a transparent resin allowing passage of ultraviolet light is used as the mold. The transfer layer is irradiated with ultraviolet light via this mold. The transparent resin allowing passage of ultraviolet light may be PDMS (polydimethylsiloxane), for example.

According to imprint lithography, once a mold tool for the mold is made, it is possible to form the recessed and protruded structure 8a in a highly reproducible fashion. Consequently, production cost can be reduced. In this case, the mold tool is a master mold, and the mold is a reverse mold.

Another preferable example of the light outcoupling structure 8 is a light diffusion layer including a matrix and light diffusion particles. The matrix has a refractive index higher than the refractive index of the protection substrate 7. The light diffusion particles have a refractive index different from the refractive index of the matrix. The light diffusion particles are dispersed in the matrix. In other words, the light outcoupling structure 8 is a light diffusion layer of a mixture of the light diffusion particles dispersed in the matrix with the refractive index higher than the refractive index of the protection substrate 7. The light diffusion particles have the refractive index different from the refractive index of the matrix.

In a situation where light is emitted from the organic EL element 5 to the atmosphere, the total reflection loss is a loss which is caused by the fact that light striking the low refractive index medium (especially, the atmosphere) at an angle not less than the critical angle from the high refractive index medium is not emitted outside. When there is a structure which causes a change in a direction of travel of light inside the medium by any means, the direction of travel of light which is not emitted outside may be changed, and thus the light may strike the interface between the mediums with the different refractive indices again. At this time, when the angle at which the light strikes the interface is less than the critical angle, this light can travel to the outside.

The light outcoupling structure 8 constituted by the matrix and the light diffusion particles diffuses light and thus the light outcoupling efficiency can be improved. In this example, the light outcoupling structure 8 is between the formation substrate 1 and the protection substrate 7 to cause dispersion of angles of light, and therefore the loss caused by the total reflection can be suppressed.

It is preferable that the matrix constituting the light outcoupling structure 8 have the refractive index higher than or equal to the refractive index of the formation substrate 1. In this case, no total reflection occurs at the interface between the formation substrate 1 and the matrix, and thus the light outcoupling efficiency can be more improved.

The light diffusion particles dispersed in the matrix have a particle size preferably in the range of 0.5 to 50 μm and more preferably in the range of 0.7 to 10 μm. This particle diameter can be measured with a laser diffraction particle size analyzer, for example.

When the particle size of the light diffusion particle is less than the above lower limit, interaction (e.g., refraction and interference) between light and the light diffusion particle may not occur, and then the angle of light may be not changed. Whereas, when the particle size of the light diffusion particle is much higher than the above upper limit, total light transmittance of the light outcoupling structure may be decreased and thus the light outcoupling efficiency may be decreased.

The light diffusion particle may be of any material with a refractive index different from the refractive index of the matrix. Preferably the material of the light diffusion particle is selected such that a difference between the refractive indices of the light diffusion particle and the matrix causes an increase in the light diffusion property.

It is preferable that the light diffusion particle does not absorb light. It is sufficient that the light diffusion particle has the refractive index different from the refractive index of the matrix. Hence, the refractive index of the light diffusion particle may be higher or lower than the refractive index of the matrix.

The light outcoupling structure 8 constituted by the matrix and the light diffusion particles is a light diffusion layer with a light diffusion property (scattering property). Provision of such a light diffusion layer can reduce the total reflection loss of light which travels from the formation substrate 1 to the light diffusion layer. Additionally, such provision of the light diffusion layer also can cause a change in the angle at which light strikes the light diffusion layer, thereby reducing the total reflection loss of such light which travels from the protection substrate 7 to the atmosphere.

The matrix used for the light outcoupling structure 8 may be of resin, for example. In a concrete example, the matrix may be of a heat or ultraviolet curable resin. When the matrix is of such resin, the formation substrate 1 can be bonded to the protection substrate 7 with the matrix. In this case, the light outcoupling structure 8 serves as the bonding layer 10. The bonding layer 10 and the light outcoupling structure 8 may be separate parts.

For example, the light diffusion particle may be of material such as a metal particle (e.g., a nano-sized metal particle and a TiO₂ particle) and a bead (e.g., a glass bead and a resin bead). The light diffusion particle of this material serves as filler.

The light outcoupling structure 8 may be of an aerosol containing holes and/or voids. In this case, the holes and voids serve as the light diffusion particles. The content ratio of the light diffusion particle to the light outcoupling structure 8 (light diffusion layer) may be in the range of 0.01 to 10% by volume, but is not limited thereto. The haze factor derived from results as described below is more important than the content ratio.

Generally, the haze factor is used as an index indicative of a quantitative value of diffuseness. The haze factor is defined as a percentage of a diffusion light transmittance (diffuse transmittance) to a total light transmittance (total transmittance) of a sample. Normally, the haze factor is increased with a decrease in the total light transmittance. It is preferable that the haze factor and the total light transmittance are high.

The concrete example of the light outcoupling structure 8 functioning as the light diffusion layer is described. This light diffusion layer is prepared by dispersing the light diffusion particles into the matrix. The matrix is made of resin (trade name “LPB-1101”, refractive index n=1.71, available from MITSUBISHI GAS CHEMICAL, Inc.) which is one of ultraviolet curable resin with a relatively high refractive index, for example. The light diffusion particle is a TiO₂ particle with an average particle size of 2 μm and is used as filler. This example has the haze factor of about 90% and the total light transmittance in the range of about 80 to 90%.

Next, an example of a process of manufacturing the planar light emitting device is described. First, to form the light outcoupling structure 8, the recessed and protruded structure 8a or the light diffusion layer is provided to the surface of the formation substrate 1 for the light exit. Thereafter, the protection substrate 7 is bonded to this surface with adhesive resin. Subsequently, a layer serving as the first electrode 2 of the organic EL element 5 is formed on the opposite surface of the formation substrate 1 from the recessed and protruded structure 8a.

Before the organic EL element 5 is formed, while the organic EL element 5 is formed, or after the organic EL element 5 is formed, that is, before the first protector 6 is bonded to the formation substrate 1, part of the formation substrate 1 corresponding to cutting lines may be pre-cut. In brief, the separate parts of the formation substrate 1 may be arranged on the surface of the protection substrate 7.

A plurality of planar light emitting devices may be formed as a single device. In this case, after the elements are formed, the single device is cut into the individual planar light emitting devices. When the glass substrate (protection substrate 7) and the resin substrate (formation substrate 1) are cut simultaneously, unintended force is likely to be applied on the resin substrate, thereby causing damages to the inside organic EL elements 5. However, when the pre-cutting is conducted in advance, only the glass substrate is divided in the cutting process. Consequently the damages to the organic EL element 5 can be reduced.

The layer of the first electrode 2 may be directly on the surface of the formation substrate 1, or may be on another layer on the surface of the formation substrate 1. Note that, the layer of the first electrode 2 is a patterned transparent conductive layer including the first electrode 2, the electrode extension part 11, and the electrode conduction part 12.

The first electrode 2 may be formed by low-temperature sputtering of an ITO (Indium Tin Oxide) target, for example. The first electrode 2 may be etched with a mask of a resist to have a predetermined pattern. The patterning is not limited to wet etching, but may be dry patterning with a laser, for example.

The first electrode 2 may be of transparent conductive oxide (e.g., IZO, AZO, and ZnO) other than ITO. When the resistance of the ITO is too high to obtain sufficient luminance uniformity, an auxiliary electrode of Ni/Cu/Ni may be used. Preferably, the electrode extension part 11 and the electrode conduction part 12 are formed at the same time of forming the first electrode 2.

It is preferable that the first electrode 2 includes a metal thin film. Generally, resin has a heat resistance property lower than a heat resistance property of glass. When the formation substrate 1 is of resin (e.g., the formation substrate 1 is a plastic substrate), there is a high possibility that the high formation temperature available for the glass substrate is not available for the formation substrate 1. For example, general PET has a heatproof temperature of about 100° C. Although PEN has a relatively high heat resistance property, the heatproof temperature of PEN is about 180° C. With regard to a relation between the formation temperature and the specific resistance of the electrode layer of the metal oxide such as ITO, the specific resistance decreases with an increase in the formation temperature.

FIG. 7 shows a graph illustrating the relation between the formation temperature and the specific resistance of the ITO layer as an example of a decrease in the specific resistance. This graph shows that, when the resin substrate is used, the high formation temperature is unavailable and thus it is difficult to sufficiently decrease the specific resistance of the electrode layer. With regard to a large substrate, the performance such as the luminance uniformity is likely to be deteriorated unless the thickness of the electrode layer of the ITO layer is increased.

For this reason, it is preferable that the first electrode 2 of the organic EL element 5 include a metal thin film. The first electrode 2 including the metal thin film can have a lowered specific resistance. Additionally, the metal thin film does not deteriorate the light transmissive property of the first electrode 2. Hence, it is possible to produce the high efficient planar light emitting device with a good conductive property. The first electrode 2 includes the metal thin film with such a thickness as to allow passage of light emitted from the organic EL element 5.

The first electrode 2 may be a single layer of the metal thin film. Or, the first electrode 2 may be a combination of a film of transparent conductive material such as ITO and a metal thin film. The specific resistance of the first electrode 2 including the metal thin film is 1/10 to 1/100 of the specific resistance of the first electrode 2 of the single ITO layer. Hence, the luminance uniformity can be improved. Additionally, the auxiliary electrode for assisting the power supply is unnecessary probably. When the first electrode 2 including the ITO film and the metal thin film, it can be easy to decrease the specific resistance by decreasing the thickness of the ITO film thereof, in contrast to the first electrode 2 consisting of the single ITO layer.

The material and the thickness of the metal thin film are appropriately selected in accordance with the desired optical performance. Especially, metal with a low light absorption property is preferable. To decrease the light absorption, the material of the metal thin film is preferably Ag or an Ag alloy.

TABLE 1 shows a reflectance, a transmittance, and an absorptance of each metal thin film (thickness is 10 nm). TABLE 1 shows that the Ag thin film has the lowest absorptance of light among the metal thin films. Ag can be used alone. Alternatively, to improve a sputtering property and stability, an Ag alloy containing tiny amounts of Mg and/or Cu is available. Even when the Ag alloy is used, it is possible to suppress absorption of light and produce the highly efficient planar light emitting device.

Examples of the material of the metal thin film include Ag. For example, as an alternative to Ag, it is possible to use an alloy of Ag and at least one from Al, Pt, Rh, Mg, Au, Cu, Zn, Ti, Pd, and Ni listed below. Especially, an MgAg alloy and a PdAg alloy are preferable. Although a content ratio of the metal other than Ag to the entire alloy depends on the alloy structure, the content ratio may be in the range of 0.001 to 3% by mass.

TABLE 1

| | t = 10 nm | t = 10 nm | t = 10 nm |
|---|---|---|---|
| METAL | REFLECTANCE | TRANSMITTANCE | ABSORPTANCE |
| Ag | 16.8 | 78.6 | 4.8 |
| Al | 48.6 | 25.8 | 25.7 |
| Mg | 17.4 | 70.3 | 12.3 |
| Au | 8.3 | 78.6 | 13.1 |
| Cu | 10.3 | 70.9 | 18.8 |
| Zn | 23.4 | 45.1 | 31.5 |
| Ti | 8.0 | 55.9 | 36.1 |
| Pd | 17.4 | 46.4 | 36.2 |
| Ni | 12.3 | 49.8 | 37.9 |
| Pt | 14.7 | 44.2 | 41.1 |
| Rh | 16.4 | 37.1 | 46.5 |

Each value is an average for a visible light region (λ = 380 to 780 nm).

After formation of the first electrode 2, layers constituting the light emitting layer 3 are stacked on the surface of the first electrode 2. The layers constituting the organic EL element 5 may be made of appropriate materials individually. These layers may be formed with appropriate methods such as deposition and coating.

Thereafter, the second electrode 4 is formed on the surface of the light emitting layer 3. In this process, the second electrode 4 is formed to be electrically connected to the electrode conduction part 12 to enable power supply to the second electrode 4. The second electrode 4 may be of appropriate metal such as Al. Consequently, the organic EL element 5 is formed on the surface of the formation substrate 1.

Next, when the coating layer 13 constitutes the second protector 9, the coating layer 13 is formed to enclose the organic EL element 5 on the surface of the formation substrate 1. In this process, the coating layer 13 is formed to cover the surface and the side surface of the peripheral part of the formation substrate 1 to be in contact with the protection substrate 7. When the pre-cutting is conducted, the coating layer 13 may be formed to extend along the pre-cut portions.

After that, the first protector 6 is formed over a region of the surface of the formation substrate 1 on which the organic EL element 5 enclosed by the coating layer 13 is present. In this process, the first protector 6 is formed to be in contact with the coating layer 13 to prevent the exposure of the surface of the formation substrate 1 to the outside. In the process of forming the first protector 6, the encapsulation member 6b may be made of resin with a moisture proof property, and the encapsulation substrate 6a of a cover glass may be bonded with such resin. Alternatively, the coating layer 13 may be formed after formation of the first protector 6.

When the planar light emitting devices are formed as the single device, at last the protection substrate 7 is cut at regions corresponding to the pre-cut portions to separate the single device into the planar light emitting devices including the elements individually. Accordingly, the planar light emitting device as shown in FIG. 1 or 2 is prepared.

As described above, the planer light emitting device of the present embodiment includes the formation substrate 1 with a light transmissive property, and the organic electroluminescence element 5 formed on the formation substrate 1. The organic electroluminescence element 5 includes the first electrode 2 with a light transmissive property, the light emitting layer 3, and the second electrode 4, which are arranged in this order from the formation substrate 1. The formation substrate 1 is formed of resin. The formation substrate 1 has the first surface (upper surface in FIG. 1) facing the organic electroluminescence element 5. The first protector 6 houses and encloses the organic electroluminescence element 5. The first protector 6 is provided to the first surface such that the edge of the formation substrate 1 is outside the first protector 6. The formation substrate 1 has the second surface (lower surface in FIG. 1) which is the opposite side of the formation substrate 1 from the organic electroluminescence element 5. The protection substrate 7 is provided to the second surface. The light outcoupling structure 8 is disposed between the protection substrate 7 and the formation substrate 1. The light outcoupling structure 8 suppresses reflection of light emitted from the organic electroluminescence element 5. The second protector 9 is provided to the formation substrate 1. The second protector 9 suppresses intrusion of moisture into the organic electroluminescence element 5 through the formation substrate 1.

In other words, the planar light emitting device of the present embodiment includes the organic electroluminescence element 5, the formation substrate 1, the light outcoupling structure 8, the first moisture preventer (first protector) 6, and the second moisture preventer 16. The organic electroluminescence element 5 includes the first surface 5a and the second surface 5b which are opposite surfaces in the thickness direction of the organic electroluminescence element 5. The organic electroluminescence element 5 is configured to emit light via the first surface 5a. The formation substrate 1 is of a resin material with a light transmissive property allowing light emitted from the organic electroluminescence element 5 to pass therethrough. The formation substrate 1 is adjacent to the first surface 5a of the organic electroluminescence element 5. The light outcoupling structure 8 is provided to the formation substrate 1 and suppresses the reflection of light emitted from the organic electroluminescence element 5 at the surface of the formation substrate 1. The first moisture preventer 6 has a moisture proof property. The first moisture preventer 6 is over the second surface 5b of the organic electroluminescence element 5 to cover the organic electroluminescence element 5. The second moisture preventer 16 has a moisture proof property, and covers the formation substrate 1 to prevent moisture from passing through the formation substrate 1 and reaching the first surface 5a of the organic electroluminescence element 5. The second moisture preventer 16 includes the overlap which overlaps the first surface 5a in the thickness direction of the organic electroluminescence element 5. The overlap is of material with a light transmissive property allowing light emitted from the organic electroluminescence element 5 to pass therethrough.

Further in the planar light emitting device of the present embodiment, the second moisture preventer 16 includes the protection substrate 7 serving as the overlap. The protection substrate 7 has a light transmissive property allowing light emitted from the organic electroluminescence element 5 to pass therethrough, and has a moisture proof property. The protection substrate 7 is on the opposite side of the formation substrate 1 from the organic electroluminescence element 5. Note that, this configuration is optional.

Further in the planar light emitting device of the present embodiment, the formation substrate 1 has the refractive index higher than the refractive index of the protection substrate 7. Note that, this configuration is optional.

Further in the planar light emitting device of the present embodiment, the light outcoupling structure 8 is the recessed and protruded structure 8a provided to the surface of the formation substrate 1. The light outcoupling structure 8a has the refractive index higher than the refractive index of the protection substrate 7. The light outcoupling structure 8a has the refractive index higher than the refractive index of the formation substrate 1. Note that, these configurations are optional.

Furthermore, the light outcoupling structure 8 may be of a different material from the formation substrate 1.

For example, the light outcoupling structure 8 may be the light diffusion layer including the matrix with the refractive index higher than the refractive index of the protection substrate 7 and the light diffusion particles which have the refractive index different from the refractive index of the matrix and are dispersed in the matrix. In other words, the light outcoupling structure 8 is the light diffusion layer of the mixture of the light diffusion particles dispersed in the matrix with the refractive index higher than the refractive index of the protection substrate 7. The light diffusion particles have the refractive index different from the refractive index of the matrix.

Alternatively, the light outcoupling structure 8 may be the light diffusion layer including the matrix with the refractive index higher than the refractive index of the formation substrate 1 and the light diffusion particles which have the refractive index different from the refractive index of the matrix and are dispersed in the matrix. In other words, the light outcoupling structure 8 is the light diffusion layer of the mixture of the light diffusion particles dispersed in the matrix with the refractive index higher than the refractive index of the formation substrate 1. The light diffusion particles have the refractive index different from the refractive index of the matrix.

In the present embodiment, the light outcoupling structure 8 is between the formation substrate 1 and the protection substrate 7. Note that, this configuration is optional.

Further in the present embodiment, the light outcoupling structure 8 may be between the formation substrate 1 and the organic electroluminescence element 5.

For example, the light outcoupling structure 8 is present between the formation substrate 1 and the organic EL element 5 and is formed on the entire surface of the formation substrate 1. In this case, a lower layer (the first electrode 2, the electrode extension part 11, and the electrode conduction part 12) of the organic EL element 5 is formed on the surface of the light outcoupling structure 8. In other words, the layer including the first electrode 2 is on the light outcoupling structure 8 on the surface (upper surface in FIG. 1) of the formation substrate 1. In this case, the light outcoupling structure 8 is formed on the surface of the formation substrate 1 before formation of the first electrode 2 and thereafter the first electrode 2 is formed on the surface of the light outcoupling structure 8.

Note that, the light outcoupling structure 8 may have the refractive index lower than the refractive index of the formation substrate 1. Further, the light outcoupling structure 8 may have the refractive index lower than the refractive index of the protection substrate 7.

Further in the planar light emitting device of the present embodiment, the second protector 9 is the coating layer 13 which covers part of the formation substrate 1 outside the first protector 6. In other words, the first moisture preventer 6 does not cover the side surface of the formation substrate 1. The second moisture preventer 16 further includes the coating layer 13 serving as the second protector 9. The coating layer 13 has a moisture proof property, and covers the side surface of the formation substrate 1. Note that, these configurations are optional.

Further in the planar light emitting device of the present embodiment, the coating layer 13 contains the desiccant. In other words, the coating layer 13 is of material containing the desiccant. Note that, this configuration is optional.

Further in the planar light emitting device of the present embodiment, the electrode connector 18 for power supply to the organic electroluminescence element 5 is provided to the coating layer 13. In other words, the planar light emitting device further includes the electrode connector 18 for power supply to the organic electroluminescence element 5. The electrode connector 18 is in the coating layer 13. Note that, this configuration is optional.

Further in the planar light emitting device of the present embodiment, the protection substrate 7 is of glass. Note that, this configuration is optional.

Further in the planar light emitting device of the present embodiment, the first electrode 2 includes the metal thin film. In other words, the organic electroluminescence element 5 includes the light emitting layer 3, and the electrode (first electrode) 2 between the light emitting layer 3 and the formation substrate 1. The first electrode 2 includes the metal thin film with such a thickness as to allow passage of light emitted from the organic electroluminescence element 5. Note that, this configuration is optional.

Furthermore in the planar light emitting device of the present embodiment, the metal thin film is formed by use of Ag or an Ag alloy. In other words, the metal thin film is of Ag or an Ag alloy. Note that, this configuration is optional.

In the resultant planar light emitting device, the formation substrate 1 is made of resin, and the light outcoupling structure 8 is provided to the formation substrate 1. Hence, the total reflection loss is reduced and the light outcoupling efficiency of the element is higher than that of the prior art. The first protector 6 and the second protector 9 enclose the organic electroluminescence element and block the moisture permeable path. Therefore, the planar light emitting device has the excellent water resistance and the excellent weather resistance, and can reduce the deterioration in the element. Consequently the highly reliable element can be obtained. Further, the formation substrate 1 is made of resin, and therefore the production cost of the planar light emitting device of the present embodiment can be lower than that of the planar light emitting device including the substrate of the high refractive index glass. Further, the moisture proof property is improved and thus the planar light emitting device can be thinned.

Accordingly, the planar light emitting device of the present embodiment can reduce the total reflection loss to improve the light outcoupling efficiency thereof and can have the excellent water resistance and the excellent weather resistance.

### EXAMPLES

Hereinafter, examples of manufacture of the planar light emitting device including the organic EL element are described.

(Formation Substrate, Light Outcoupling Layer, Protection Substrate)

A PET substrate was used as the formation substrate 1 of the organic EL element. The PET substrate has refractive index higher than normal glass and is of a typical plastic material. A prism sheet with an adhesive was attached to a light exit surface of this substrate (opposite surface of the substrate from the light emitting layer 3). The prism sheet was dried in vacuum in advance. The prism sheet is a light diffusion film (available from KIMOTO; product name: LIGHT-UP (registered trademark) GM3). This light diffusion film is a sheet provided at its surface with the recessed and protruded structure 8a.

The protection substrate 7 prevents moisture from reaching the organic EL element 5 and has a light transmissive property. Hence, a glass substrate was used as the protection substrate 7. A surface of this glass substrate was coated with an adhesive sheet (acrylic transparent adhesive; refractive index n=1.48). The glass substrate was attached to the prism sheet on the surface of the formation substrate 1.

As a result, the formation substrate 1 carrying the light outcoupling structure 8 and the protection substrate 7 at the external (light outcoupling side) surface was obtained.

(First Electrode)

Next, an ITO layer with a thickness of 100 nm was formed on the surface on the opposite side of the formation substrate 1 from the light outcoupling structure 8 by use of low-temperature sputtering (process temperature is not greater than 100° C.) of an ITO target. The ITO layer was used for formation of the first electrode 2, the electrode extension part 11, and the electrode conduction part 12.

Next, a positive type resist (trade name “OFPR800LB”, available from TOKYO OHKA KOGYO co., ltd.) was applied to the entire surface of the ITO film and then was baked. Subsequently, the resist was exposed to ultraviolet through a separately prepared glass mask, and exposed part of the resist was removed with a developer (trade name “NMD-W”, available from TOKYO OHKA KOGYO co., ltd.). Thereby, the resist was patterned.

Thereafter, a portion of the ITO film which is not covered with the resist mask was etched with an etchant (trade name “ITO-06N”, available from KANTO CHEMICAL co., Inc.), and finally the patterned resist was removed with a resist remover solution (trade name “stripper 106”, available from TOKYO OHKA KOGYO co., ltd.). Thereby, the formation substrate 1 with the patterned ITO layer was obtained.

The resultant formation substrate 1 was ultrasonically washed with a neutral detergent, and then washed with pure water. Then, washed formation substrate 1 was dried at 80° C. for about 2 hours in vacuum. Subsequently, the dried formation substrate 1 was subjected to treatment using ultraviolet (UV) and ozone (O₃) for 10 minutes.

(Precutting)

Next, pre-cutting was conducted. In this pre-cutting, the PET substrate and the prism sheet was cut along cutting lines for separation of elements without cutting the glass substrate.

(Formation of Organic Electroluminescence Element)

The formation substrate 1 was disposed within a chamber of a vacuum vapor deposition apparatus. Then, the hole transport layer was formed on the a region of the ITO layer serving as the first electrode 2 (anode). The hole transport layer is a layer of bis[N-(1-naphthyl)-N-phenyl]benzidine (hereinafter referred to as “α-NPD”).

Next, the light emitting material layer with a thickness of 20 nm was formed. The light emitting material layer is a layer of aluminum tris(quinoline-8-olate) (referred to as “Alq3”) doped with 5% rubrene.

Subsequently, the electron transport layer with the thickness of 40 nm was formed. The electron transport layer is a layer of Alq3.

Further, the electron injection layer with the thickness of 1 nm is formed on the electron transport layer. The electron injection layer is a layer of LiF.

Finally, the second electrode 4 (cathode) with the thickness of 80 nm was formed by vapor deposition. The second electrode 4 is a layer of Al.

Consequently, the organic EL element 5 including the first electrode 2, the light emitting layer 3, and the second electrode 4 stacked in this order was prepared.

(Formation of Second Protector)

Next, the coating layer 13 serving as the second protector 9 was formed on the surface of the formation substrate 1 to surround the organic EL element 5. Further, edge surfaces of the pre-cut PET substrate (formation substrate 1) were covered with the coating layer 13, and the coating layer 13 was formed to be in contact with the protection substrate 7. By doing so, the upper surface and the side surface of the formation substrate 1 were covered with the coating layer 13.

Note that, the coating layer 13 was made of a moisture proof resin composition containing desiccant. Thus, the structure capable of preventing moisture intrusion through the edge surfaces of the formation substrate 1 was formed.

(Encapsulation by First Protector)

The first protector 6 was formed by use of dam and fill solid-sealing.

First, a low permeable epoxy resin was printed on the surrounding area of the organic EL element 5 to form a ring-shaped dam. In this process, the circular dam was formed to be in contact with the second protector 9 (coating layer 13) to prevent exposure of part of the formation substrate 1 outside the ring-shaped dam.

Next, filling material containing hygroscopic material and shock-absorbing material was dropped on the organic EL element so as to fill the inside of the ring-shaped dam of the epoxy resin with the filling material.

At last, the cover glass was attached on the ring-shaped dam and then the filling material was cured. Thus, the organic EL element 5 was encapsulated by the first protector 6 constituted by the encapsulation member 6b and the encapsulation substrate 6a.

(Individual Separation by Cutting)

At last, grooves were formed in regions between the elements by a diamond cutter, and then the glass substrate was cut by a scriber.

Thus, the planar light emission element including the organic EL element 5 enclosed by glass was obtained.

### Second Embodiment

FIG. 8 shows an example of the planar light emitting device of the second embodiment. Like the embodiment shown in FIG. 1, in the present planar light emitting device, the organic EL element 5 is formed on the surface of the formation substrate 1 with a light transmissive property. The organic EL element 5 includes the first electrode 2, the light emitting layer 3, and the second electrode 4 which are arranged in this order from the formation substrate 1. The first electrode 2 has a light transmissive property. Further, like the embodiment shown in FIG. 1, the first protector 6 (61), the protection substrate 7, the light outcoupling structure 8, and the bonding layer 10 are provided. In the present embodiment, the second protector 9 has the inside block structure. For example, the second protector 9 is a gas barrier layer 14 formed on the surface of the formation substrate 1 close to the organic EL element 5. The other configurations of the planar light emitting device of the present embodiment are the same as those of the planar light emitting device of the first embodiment. Hence, the configurations described in the first embodiment are available for the configurations (e.g., the first protector 6 and the light outcoupling structure 8) other than the second protector 9 of the present embodiment. Note that, the optional configurations in the first embodiment are also optional in the present embodiment.

In the planar light emitting device of the present embodiment, the second moisture preventer 16 (162) are constituted by the gas barrier layer 14 serving as the second protector 9 and the protection substrate 7.

The protection substrate 7 has a light transmissive property allowing light emitted from the organic EL element 5 to pass therethrough, and has a moisture proof property. The protection substrate 7 is on the opposite side of the formation substrate 1 from the organic EL element 5.

The gas barrier layer 14 has a light transmissive property allowing light emitted from the organic EL element 5 to pass therethrough, and has a moisture proof property. The gas barrier layer 14 is between the formation substrate 1 and the organic EL element 5.

In summary, the second moisture preventer 162 includes the protection substrate 7 and the gas barrier layer 14 which serve as the overlap.

Hereinafter, the gas barrier layer 14 is described in more detail.

The second protector 9 constituted by the gas barrier layer 14 is between the formation substrate 1 and the organic EL element 5 and covers the entire surface of the formation substrate 1. In this case, the lower layer (the first electrode 2, the electrode extension part 11, and the electrode conduction part 12) of the organic EL element 5 is formed on a surface of the gas barrier layer 14.

In other words, in the present embodiment, the layer including the first electrode 2 is on the gas barrier layer 14 on the surface (upper surface in FIG. 8) of the formation substrate 1. In a case where the gas barrier layer 14 constitutes the second protector 9, the gas barrier layer 14 is formed on the surface of the formation substrate 1 before formation of the first electrode 2, and then the first electrode 2 is formed on the surface of the gas barrier layer 14. Note that, the layer including the first electrode 2 is a transparent conductive layer patterned to include the first electrode 2, the electrode extension part 11, and the electrode conduction part 12.

In the present embodiment, the entire organic EL element 5 is enclosed with the first protector 6 and the second protector 9 and therefore is protected. Hence, it is possible to efficiently suppress moisture intrusion. Further, when the protection substrate 7 is bonded to the formation substrate 1, the protection substrate 7 can serve to suppress moisture intrusion, and thus the moisture proof property can be improved more.

The gas barrier layer 14 may be of the same material as the second protector 9 according to the embodiment shown in FIG. 1. Especially, it is preferable that the gas barrier layer 14 be of a light transmissive and low permeable material. For example, the gas barrier layer 14 may be of inorganic material such as SiO₂ and TiO₂. Films of such inorganic material may be formed with sputtering.

To further improve a gas barrier property of the gas barrier layer 14, the gas barrier layer 14 may include two or more layers of inorganic material, or may have a layered structure in which organic films and inorganic films are stacked alternately. When the gas barrier layer 14 is a single resin layer, or includes a resin layer, it is preferable that the gas barrier layer 14 contain desiccant. The desiccant can contribute to improvement of the moisture proof property of the gas barrier layer 14, and thus can enhance the effect of prevention of moisture from reaching the organic EL element 5.

To improve the gas barrier property of the gas barrier layer 14, it is preferable that the gas barrier layer 14 have a thickness of 100 nm or more. The upper limit of the thickness of the gas barrier layer 14 is not limited to a particular one. To allow the gas barrier layer 14 to have a required light transmissive property, it is preferable that the gas barrier layer 14 have the thickness of 10000 nm or less. When the gas barrier layer 14 is an inorganic film which does not absorb light, the thickness of the gas barrier layer 14 has no particular upper limit. Preferably, optical properties (e.g., the thickness and the refractive index) of the gas barrier layer 14 are selected in advance in view of passage of light through the gas barrier layer 14.

Preferably, an average of differences in refractive indices between the gas barrier layer 14 and the formation substrate 1 for wavelengths within the visible spectrum is not greater than 0.05. In other words, a difference between an average of the refractive indices of the gas barrier layer 14 for the wavelengths within the visible spectrum and an average of the refractive indices of the formation substrate 1 for the wavelengths within the visible spectrum is 0.05 or less.

When the refractive index of the gas barrier layer 14 is equal to the refractive index of the formation substrate 1 or a difference between the refractive indices between the gas barrier layer 14 and the formation substrate 1 is decreased as possible, the undesired influence caused by optical interference by the gas barrier layer 14 can be reduced as possible. Further in this case, in the design of the element, the gas barrier layer 14 and the formation substrate 1 may be treated as a single part. Hence, there is no need to select the thickness of the organic EL element 5 with special consideration to the gas barrier layer 14. Thus, the optical design of the element can be facilitated.

As described above, the second protector 9 of the planar light emitting device is the gas barrier layer 14 which is formed on the surface (upper surface in FIG. 8) of the formation substrate 1 close to the organic EL element 5.

In other words, in the planar light emitting device of the present embodiment, the second moisture preventer 16 (162) includes the gas barrier layer 14 serving as the overlap thereof. The gas barrier layer 14 has the light transmissive property allowing light emitted from the organic electroluminescence element 5 to pass therethrough, and has the moisture proof property. The gas barrier layer 14 is between the formation substrate 1 and the organic electroluminescence element 5.

Additionally, in the planar light emitting device of the present embodiment, the second moisture preventer 16 (162) includes the protection substrate 7 serving as the overlap. The protection substrate 7 has the light transmissive property allowing light emitted from the organic EL element 5 to pass therethrough, and has the moisture proof property. The protection substrate 7 is on the opposite side of the formation substrate 1 from the organic EL element 5.

In the planar light emitting device of the present embodiment, the average of the differences in the refractive indices between the gas barrier layer 14 and the formation substrate 1 for the wavelengths within the visible spectrum is not greater than 0.05. In other words, the gas barrier layer 14 satisfies the condition that the average of the differences between the refractive indices of the gas barrier layer 14 and the formation substrate 1 with regard to light rays in the visible range is not greater than 0.05. Note that, this configuration is optional.

In the planar light emitting device of the present embodiment, the protection substrate 7 is optional. Hence, in the present embodiment, the protection substrate 7 may be removable. In other words, the protection substrate 7 is attached to the formation substrate 1 in a removable fashion.

In this case, the planar light emitting device can be obtained by removing the protection substrate 7. Thus, the planar light emitting device can be more thinned. When the formation substrate 1 is of a flexible resin material, the flexible planar light emitting device can be produced.

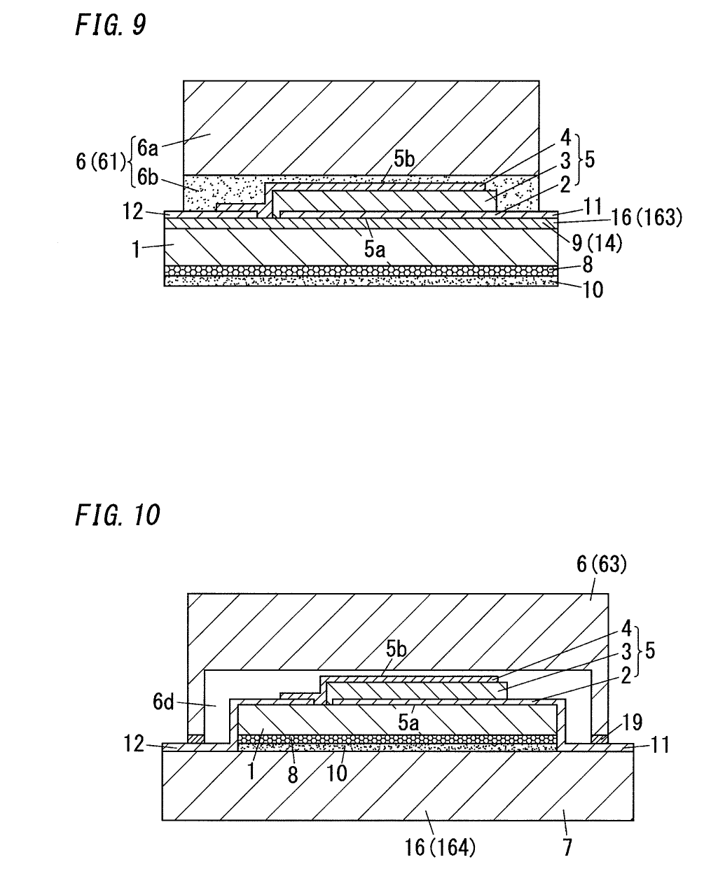

FIG. 9 shows an example of the planar light emitting device from which the protection substrate 7 is removed (i.e., a modification of the planar light emitting device of the second embodiment). For example, in the embodiment shown in FIG. 8, the protection substrate 7 may be bonded to the formation substrate 1 with the bonding layer 10 with such adhesiveness that the protection substrate 7 is removable from the formation substrate 1. In this case, the present planar light emitting device can be obtained by removing the protection substrate 7.

When a layer bonding the protection substrate 7 to the formation substrate 1 (or the light outcoupling structure 8 on the surface of the formation substrate 1) has such adhesiveness as to allow removal of the protection substrate 7 from the formation substrate 1, such a device can be produced.

Note that, FIG. 9 shows the embodiment in which the bonding layer 10 is attached to the formation substrate 1 and is part of the planar light emitting device. However, the bonding layer 10 may be removed together with the protection substrate 7 or be removed after the removal of the protection substrate 7. In short, the bonding layer 10 may not be part of the planar light emitting device.

When the gas barrier layer 14 can improve the gas barrier property sufficiently, the protection substrate 7 is unnecessary. The device can be of wider application.

In summary, the planar light emitting device shown in FIG. 9 includes the organic electroluminescence element 5, the formation substrate 1, the first moisture preventer (first protector) 6, and the second moisture preventer (second protector) 16 (163). The second moisture preventer 163 is constituted by the gas barrier layer 14 serving as the second protector 9.

Note that, the planar light emitting device shown in FIG. 9 may be formed by use of a substrate different from the protection substrate 7, for example. In this case, the substrate is removed from the planar light emitting device after formation of the planar light emitting device.

### Third Embodiment

FIG. 10 shows an example of the planar light emitting device of the third embodiment. The planar light emitting device of the present embodiment includes the organic EL element 5 same as that of the first embodiment but is different from the planar light emitting device in the first protector (moisture preventer) 6 (63) and the second moisture preventer 16 (164).

The other configurations of the planar light emitting device of the present embodiment are the same as those of the planar light emitting device of the first embodiment. Hence, the configurations described in the first embodiment are available for the configurations (e.g., the light outcoupling structure 8) other than the first moisture preventer 6 and the second moisture preventer 16 of the present embodiment. The configurations common to the present embodiment and the first embodiment are designated by the same reference numerals and no explanations thereof are deemed necessary. Note that, the optional configurations in the first embodiment are also optional in the present embodiment.

In the present embodiment, the second moisture preventer 164 is constituted by the protection substrate 7. Besides, the second moisture preventer 164 may include the same gas barrier layer 14 of the second embodiment. In this case, the second moisture preventer 164 is constituted by the gas barrier layer 14 and the protection substrate 7.

The first protector 63 cooperates with the second moisture preventer (protection substrate 7) to form a housing which accommodates the organic EL element 5 to protect the organic EL element 5 from moisture.

The first protector 63 is of a glass substrate (e.g., an inexpensive glass substrate such as a soda lime glass substrate and a non-alkali glass substrate), for example. The first protector 63 is provided with an accommodation recess 6d in a facing surface (lower surface in FIG. 10) opposite the protection substrate 7. The accommodation recess 6d accommodates the organic EL element 5.

The first protector 63 is attached to the protection substrate 7 with a bonding member 19. For example, the first protector 63 is bonded to the protection substrate 7 at an entire surrounding area of the accommodation recess 6d of the facing surface of the first protector 63. Consequently, the housing protecting the organic EL element 5 from moisture is formed.

In the present embodiment, the electrode extension part 11 on the formation substrate 1 extends to the surface (the surface facing the first protector 63, the upper surface in FIG. 10) of the protection substrate 7. Further, the electrode extension part 11 extends outside the accommodation recess 6d. In this case, the electrode extension part 11 has a portion (right end portion in FIG. 10) outside the accommodation recess 6d, and this portion serves as an external connection electrode for applying an electrical potential to the first electrode 2. Likewise, the electrode extension part 12 on the formation substrate 1 extends to the surface (the surface facing the first protector 63, the upper surface in FIG. 10) of the protection substrate 7. Further, the electrode extension part 12 extends outside the accommodation recess 6d. In this case, the electrode extension part 12 has a portion (left end portion in FIG. 10) outside the accommodation recess 6d, and this portion serves as an external connection electrode for applying an electrical potential to the second electrode 4.

The bonding member 19 may be low-melting-point glass, an adhesive film, thermoset resin, ultraviolet curing resin, and an adhesive agent (e.g., epoxy resin, acrylic resin, and silicone resin), for example.

Besides, a water absorption member (not shown) absorbing moisture may be attached to an inner bottom surface of the accommodation recess 6d of the first protector 63. For example, the water absorption member may be a calcium oxide-type desiccant agent (a getter material containing calcium oxide).

Instead of extending the electrode extension parts 11 and 12 as described above, external connection electrodes (not shown) may be provided on the surface (the surface facing the first protector 63) of the protection substrate 7. These external connection electrodes are electrically connected to the first electrode 2 and the second electrode 4 of the organic EL element 5, respectively. In this case, the first electrode 2 and the second electrode 4 are electrically connected to the external connection electrodes through the electrode extension parts 11 and 12, respectively.

For example, the light outcoupling structure 8 is of a different material from the formation substrate 1. Concretely, the light outcoupling structure 8 may be a light diffusion sheet having a recessed and protruded structural part such as a prism sheet and a light diffusion film. Alternatively, the light outcoupling structure 8 may be formed in the surface of the formation substrate 1 by transferring the recessed and protruded structural part to the formation substrate 1 by means of imprint lithography (nano-imprint lithography). Alternatively, the light outcoupling structure 8 may be a light diffusion layer of a mixture of the light diffusion particles dispersed in the matrix, the light diffusion particles having the refractive index different from the refractive index of the matrix.

In a similar manner to the first and second embodiments, the light outcoupling structure 8 is between the formation substrate 1 and the protection substrate 7.

In the planar light emitting device of the present embodiment, the first moisture preventer (first protector) 63 is configured to cooperate with the second moisture preventer 164 to form the housing which accommodates the organic electroluminescence element 5 to protect the organic electroluminescence element 5 from moisture.

Accordingly, the planar light emitting device of the present embodiment can reduce the total reflection loss to improve the light outcoupling efficiency thereof and can have the excellent water resistance and the excellent weather resistance.

1. A planar light emitting device, comprising:
an organic electroluminescence element including a first surface and a second surface which are opposite surfaces in a thickness direction of the organic electroluminescence element, the organic electroluminescence element being configured to emit light via the first surface;
a formation substrate which is of a resin material with a light transmissive property allowing light emitted from the organic electroluminescence element to pass therethrough, and is adjacent to the first surface of the organic electroluminescence element;
a light outcoupling structure provided to the formation substrate and suppressing reflection of light emitted from the organic electroluminescence element at a surface of the formation substrate;
a first moisture preventer which has a moisture proof property, and is over the second surface of the organic electroluminescence element to cover the organic electroluminescence element; and
a second moisture preventer which has a moisture proof property, and covers the formation substrate to prevent moisture from passing through the formation substrate and reaching the first surface of the organic electroluminescence element,
the second moisture preventer including an overlap which overlaps the first surface in the thickness direction of the organic electroluminescence element,
a whole of the formation substrate being on a surface of the overlap, and
the overlap being of material with a light transmissive property allowing light emitted from the organic electroluminescence element to pass therethrough.

2. The planar light emitting device according to claim 1, wherein:
the second moisture preventer includes a protection substrate serving as the overlap;
the protection substrate has a light transmissive property allowing light emitted from the organic electroluminescence element to pass therethrough, and has a moisture proof property; and
the protection substrate is on an opposite side of the formation substrate from the organic electroluminescence element.

3. The planar light emitting device according to claim 2, wherein
the first moisture preventer does not cover a side surface of the formation substrate.

4. The planar light emitting device according to claim 3, wherein:
the second moisture preventer further includes a coating layer; and
the coating layer has a moisture proof property, and covers the side surface of the formation substrate.

5. The planar light emitting device according to claim 4, wherein
the coating layer is of material containing desiccant.

6. The planar light emitting device according to claim 4, wherein:
the planar light emitting device further comprises an electrode connector for power supply to the organic electroluminescence element; and
the electrode connector is in the coating layer.

7. The planar light emitting device according to claim 2, wherein
the first moisture preventer cooperates with the protection substrate of the second moisture preventer to form a housing which accommodates the organic electroluminescence element to protect the organic electroluminescence element from moisture.

8. The planar light emitting device according to claim 2, wherein
the light outcoupling structure is a recessed and protruded structure provided to the surface of the formation substrate.

9. The planar light emitting device according to claim 8, wherein
the light outcoupling structure has a refractive index higher than a refractive index of the protection substrate.

10. The planar light emitting device according to claim 8, wherein
the light outcoupling structure has a refractive index higher than a refractive index of the formation substrate.

11. The planar light emitting device according to claim 2, wherein
the light outcoupling structure is of a different material from the formation substrate.

12. The planar light emitting device according to claim 11, wherein
the light outcoupling structure is between the formation substrate and the protection substrate.

13. The planar light emitting device according to claim 11, wherein
the light outcoupling structure is between the formation substrate and the organic electroluminescence element.

14. The planar light emitting device according to claim 11, wherein
the light outcoupling structure is a light diffusion layer of a mixture of light diffusion particles dispersed in a matrix with a refractive index higher than a refractive index of the protection substrate, the light diffusion particles having a refractive index different from the refractive index of the matrix.

15. The planar light emitting device according to claim 11, wherein,
the light outcoupling structure is a light diffusion layer of a mixture of light diffusion particles dispersed in a matrix with a refractive index higher than a refractive index of the formation substrate, the light diffusion particles having a refractive index different from the refractive index of the matrix.

16. The planar light emitting device according to claim 11, wherein
the light outcoupling structure has a refractive index lower than a refractive index of the formation substrate.

17. The planar light emitting device according to claim 11, wherein
the light outcoupling structure has a refractive index lower than a refractive index of the protection substrate.

18. The planar light emitting device according to claim 2, wherein
the formation substrate has a refractive index higher than a refractive index of the protection substrate.

19. The planar light emitting device according to claim 2, wherein
the protection substrate is of glass.

20. The planar light emitting device according to claim 1, wherein:
the second moisture preventer includes a gas barrier layer serving as the overlap;
the gas barrier layer has a light transmissive property allowing light emitted from the organic electroluminescence element to pass therethrough, and has a moisture proof property; and
the gas barrier layer is between the formation substrate and the organic electroluminescence element.

21. The planar light emitting device according to claim 20, wherein
the gas barrier layer satisfies a condition that an average of differences between refractive indices of the gas barrier layer and the formation substrate with regard to light rays in a visible range is not greater than 0.05.

22. The planar light emitting device according to claim 20, wherein:
the second moisture preventer includes a protection substrate serving as the overlap;
the protection substrate has a light transmissive property allowing light emitted from the organic electroluminescence element to pass therethrough, and has a moisture proof property; and
the protection substrate is on an opposite side of the formation substrate from the organic electroluminescence element.

23. The planar light emitting device according to claim 3, wherein
the protection substrate is attached to the formation substrate in a removable fashion.

24. The planar light emitting device according to claim 1, wherein:
the organic electroluminescence element includes
a light emitting layer, and
an electrode between the light emitting layer and the formation substrate; and
the electrode includes a metal thin film with such a thickness as to allow passage of light emitted from the organic electroluminescence element.

25. The planar light emitting device according to claim 24, wherein
the metal thin film is of Ag or an Ag alloy.
